(19) United States
(12) Patent Application Publication
(10) Pub. No.: US 2024/0113682 A1
(43) Pub. Date: Apr. 4, 2024

(54) ACOUSTIC WAVE DEVICE

(71) Applicant: Murata Manufacturing Co., Ltd., Nagaokakyo-shi (JP)

(72) Inventor: Sho NAGATOMO, Nagaokakyo-shi (JP)

(21) Appl. No.: 18/537,872

(22) Filed: Dec. 13, 2023

Related U.S. Application Data
(63) Continuation of application No. PCT/JP2022/028145, filed on Jul. 20, 2022.

(30) Foreign Application Priority Data
Jul. 21, 2021 (JP) 2021-120521

(51) Int. Cl. H03H 9/145; H03H 9/25

(52) U.S. Cl. CPC H03H 9/14552; H03H 9/25

(57) ABSTRACT

An acoustic wave device includes a piezoelectric material layer, and an IDT electrode on the piezoelectric material layer and including first electrode fingers and second electrode fingers arranged periodically. The electrode fingers each include at least one electrode layer including at least one of Nb, Pd, or Ni. A sum of thicknesses of the at least one electrode layer, calculated assuming that the electrode layer(s) includes Mo and based on a density ratio between the electrode layer(s) and Mo, is at least about 10% of a spatial period of the electrode fingers.

### CROSS REFERENCE TO RELATED APPLICATIONS

This application claims the benefit of priority to Japanese Patent Application No. 2021-120521 filed on Jul. 21, 2021 and is a Continuation application of PCT Application No. PCT/JP2022/028145 filed on Jul. 20, 2022. The entire contents of each application are hereby incorporated herein by reference.

### BACKGROUND OF THE INVENTION

### 1. Field of the Invention

The present invention relates to an acoustic wave device.

### 2. Description of the Related Art

Acoustic wave devices have been widely used in, e.g., filters for mobile phones. Japanese Patent No. 5716050 identified below discloses an exemplary acoustic wave device. The acoustic wave device includes an IDT (Interdigital Transducer) electrode provided on a piezoelectric substrate. High-density metals, such as molybdenum and tungsten, are described as materials for the IDT electrode. Japanese Patent No. 5716050 also states that when molybdenum is used for the IDT electrode, the thickness of the IDT electrode should be 0.0375λ or more in order to increase the electromechanical coupling coefficient.

### SUMMARY OF THE INVENTION

The use of a high-density metal for an IDT electrode makes it possible to reduce the velocity of a SAW (Surface Acoustic Wave). This can reduce bulk wave radiation, and therefore can convert the mode of acoustic waves from a leaky wave mode into a Love wave mode. The present inventors discovered that the use of a Love wave mode with the IDT electrode described in Japanese Patent No. 5716050 achieves lower temperature characteristics as compared to the use of a leaky wave mode.

Preferred embodiments of the present invention provide acoustic wave devices that each improve temperature characteristics.

An acoustic wave device according to a preferred embodiment of the present invention includes a piezoelectric material layer, and an IDT electrode on the piezoelectric material layer and including a plurality of electrode fingers arranged periodically. The electrode fingers each include at least one electrode layer including at least one of Nb, Pd, or Ni. A sum of thicknesses of the at least one electrode layer, calculated assuming that the at least one electrode layer includes Mo and based on a density ratio between the at least one electrode layer and Mo, is at least about 10% of a spatial period of the electrode fingers.

According to the acoustic wave devices of preferred embodiments of the present invention, it is possible to improve the temperature characteristics.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a plan view of an acoustic wave device according to a first preferred embodiment of the present invention.

FIG. 2 is a cross-sectional view taken along line I-I in FIG. 1.

FIG. 3 is a diagram showing the relationship between the temperature coefficient TCm of the elastic modulus of electrode fingers and the acoustic velocity temperature coefficient TCVr at a resonance point when the normalized thickness of the electrode fingers is about 10%.

FIG. 4 is a diagram showing the relationship between the content of Mo in NbMo and dc44/dT.

FIG. 5 is a diagram showing the relationship between the content of Mo in NbMo and the density.

FIG. 6A is a diagram showing the relationship between the temperature coefficient TCm of the elastic modulus of electrode fingers and a difference ΔTCV in the acoustic velocity temperature coefficient when the normalized thickness of the electrode fingers is about 8%, FIG. 6B is a diagram showing the relationship between the temperature coefficient TCm of the elastic modulus of electrode fingers and the difference ΔTCV in the acoustic velocity temperature coefficient when the normalized thickness of the electrode fingers is about 10%, FIG. 6C is a diagram showing the relationship between the temperature coefficient TCm of the elastic modulus of electrode fingers and the difference ΔTCV in the acoustic velocity temperature coefficient when the normalized thickness of the electrode fingers is about 12%, and FIG. 6D is a diagram showing the relationship between the temperature coefficient TCm of the elastic modulus of electrode fingers and the difference ΔTCV in the acoustic velocity temperature coefficient when the normalized thickness of the electrode fingers is about 14%, for example.

FIG. 7 is an elevational cross-sectional view of an acoustic wave device according to a second preferred embodiment of the present invention.

FIG. 8 is an elevational cross-sectional view of an acoustic wave device according to a third preferred embodiment of the present invention.

FIG. 9 is an elevational cross-sectional view of an acoustic wave device according to a fourth preferred embodiment of the present invention.

### DETAILED DESCRIPTION OF THE PREFERRED EMBODIMENTS

Specific preferred embodiments of the present invention will now be described with reference to the drawings to clarify the present invention.

It should be noted that the preferred embodiments are illustrated by way of example, and that any partial replacement or combination will be possible between features of different preferred embodiments.

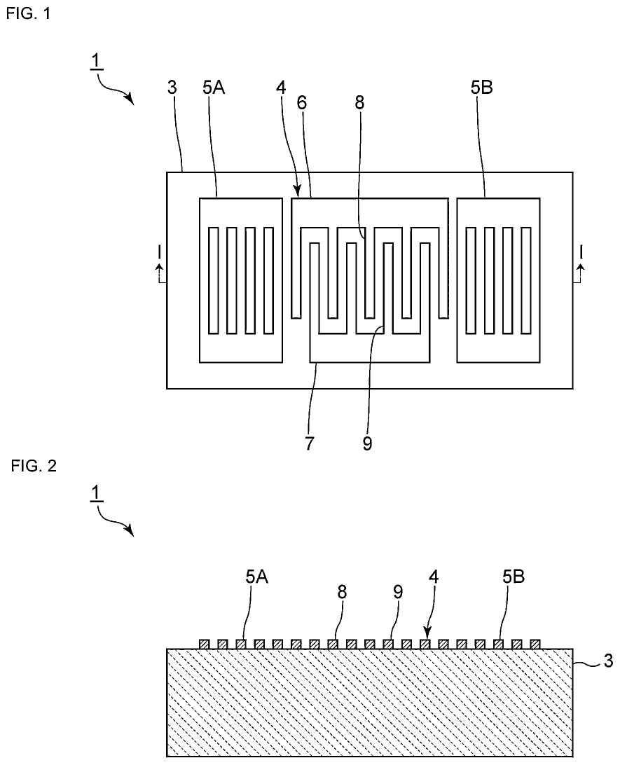

FIG. 1 is a plan view of an acoustic wave device according to a first preferred embodiment of the present invention. FIG. 2 is a cross-sectional view taken along line I-I in FIG. 1.

As shown in FIGS. 1 and 2, the acoustic wave device 1 includes a piezoelectric substrate. The piezoelectric substrate of this preferred embodiment is composed solely of a piezoelectric material layer 3, for example. However, the piezoelectric substrate may be a laminated substrate including the piezoelectric material layer 3.

An IDT electrode 4 is provided on the piezoelectric material layer 3. Acoustic waves are excited by applying an alternating current voltage to the IDT electrode 4. In this preferred embodiment, an SH mode is excited as a main mode. More specifically, the acoustic wave device 1 uses an SH mode in a Love wave state. The phrase “SH mode in a Love-wave state” means that the SH mode is in a non-leaky state in the thickness direction of the piezoelectric material layer 3.

A pair of reflectors 5A and 5B are provided on the piezoelectric material layer 3 on both sides of the IDT electrode 4 in the direction of propagation of acoustic waves. The acoustic wave device 1 of this preferred embodiment is a surface acoustic wave resonator. However, the acoustic wave device of the present invention may be, for example, a filter device or multiplexer which includes a plurality of acoustic wave resonators.

Lithium tantalate is preferably used for the piezoelectric material layer 3, for example. More specifically, 42YX—LiTaO₃ is preferably used for the piezoelectric material layer 3, for example. However, the cut angle and material of the piezoelectric material layer 3 are not limited to the above. Lithium niobate such as LiNbO₃ may be used for the piezoelectric material layer 3, for example.

As shown in FIG. 1, the IDT electrode 4 includes a first busbar 6, a second busbar 7, a plurality of first electrode fingers 8, and a plurality of second electrode fingers 9. The first busbar 6 and the second busbar 7 are disposed opposite to each other. One end of each first electrode finger 8 is connected to the first busbar 6. One end of each second electrode finger 9 is connected to the second busbar 7. The first electrode fingers 8 and the second electrode fingers 9 are arranged periodically. The first electrode fingers 8 and the second electrode fingers 9 are interdigitated into each other. The first electrode fingers 8 and the second electrode fingers 9 hereinafter may sometimes be referred to simply as the electrode fingers.

The IDT electrode 4 includes a single electrode layer. However, the IDT electrode 4 may include at least one electrode layer. Thus, the IDT electrode 4 may have multiple electrode layers.

The electrode layer(s) of the IDT electrode 4 comprises NbMo. NbMo is an alloy of Nb and Mo. However, the material of the electrode layer(s) is not limited to the above. For example, NiTi, CoPd, or NiFe can also be used as a material for the electrode layer(s). The at least one electrode layer may comprise at least one of Nb, Pd, or Ni. It is particularly preferred that the at least one electrode layer includes an alloy including Nb. The same material as that of the IDT electrode 4 is used for the pair of reflectors 5A and 5B.

Mo equivalent thickness is herein used as the thickness of an electrode layer. The Mo equivalent thickness of an electrode layer refers to the thickness of the electrode layer as calculated on the assumption that the electrode layer includes Mo and based on the density ratio between the electrode layer and Mo. In particular, the Mo equivalent thickness tn of an electrode layer is represented by the following equation: tn=r×te, where r is the density ratio ρe/ρMo, with ρe being the density of the electrode layer and ρMo being the density of Mo, and te is the thickness of the electrode layer. When the electrode fingers each include multiple electrode layers, the Mo equivalent thickness of the electrode fingers is the sum of the Mo equivalent thicknesses of the multiple electrode layers. For example, when each electrode finger is a laminate of m electrode layers, the Mo equivalent thickness of the electrode fingers is Σtnk (1≤k≤m), where tnk is the Mo equivalent thickness of the k-th electrode layer. When each electrode finger includes only one electrode layer, the sum of the Mo equivalent thicknesses of the electrode layer(s) corresponds to the Mo equivalent thickness of the one electrode layer.

On the other hand, the thickness of the electrode fingers herein may also be expressed in terms of normalized thickness normalized by the spatial period of the electrode fingers of the IDT electrode 4. The normalized thickness of the electrode fingers is the ratio of the thickness of the electrode fingers to the spatial period. More specifically, the normalized thickness of the electrode fingers is the ratio of the Mo equivalent thickness of the electrode fingers to the spatial period. When the pitch of the electrode fingers of the IDT electrode 4 is represented by p, the spatial period of the electrode fingers is 2p. The pitch of the electrode fingers is the distance between the centers of adjacent first electrode finger 18 and second electrode finger 19. For example, when the Mo equivalent thickness of the electrode fingers is 2p, the normalized thickness of the electrode fingers is 100%.

One of the unique features of this preferred embodiment is that the electrode layer(s) of each electrode finger includes Nb, and that the sum of the Mo equivalent thicknesses of the electrode layer(s) is at least about 10% of the spatial period of the electrode fingers, that is, the normalized thickness of the electrode fingers is at least about 10%, for example. This makes the SH mode a Love wave state. The inclusion of Nb in the electrode layer(s) with the SH mode in such a state can improve the temperature characteristics. More specifically, the absolute value of the acoustic velocity temperature coefficient TCV [ppm/K] can be reduced. The electrode layer(s) may include at least one of Nb, Pd, or Ni. The following description first illustrates the features of the SH mode in a Love wave state, and then illustrates the improvement in the temperature characteristics achieved by the electrode layer(s) according to this preferred embodiment.

When acoustic waves are in a leaky state, the piezoelectric material layer has a dominant influence on various characteristics of the acoustic waves. Thus, the electrode fingers make no significant contribution to various characteristics of the acoustic waves. On the other hand, when acoustic waves are in a non-leaky state, e.g., when the SH mode is in a Love wave state, the displacement distribution of the acoustic waves is concentrated at the surface of the piezoelectric material layer and in the electrode fingers. Thus, the electrode fingers make a large contribution to various characteristics of the acoustic waves. For example, the temperature coefficient TCm [ppm/K] of the elastic modulus of the electrode fingers makes a large contribution to the acoustic velocity temperature coefficient TCV. The larger the mass addition by the electrode fingers, the larger the contribution.

When the SH mode is in a Love wave state and the mass addition by the electrode fingers is large, a change in the temperature coefficient TCm of the elastic modulus causes a significant change, e.g., in the acoustic velocity temperature coefficient TCVr [ppm/K] at a resonance point or the acoustic velocity temperature coefficient TCVa [ppm/K] at an anti-resonance point. Further, a change in TCm also causes a significant change in the difference ΔTCV [ppm/K] between the acoustic velocity temperature coefficient at a resonance point and that at an anti-resonance point. A comparison will now be made between the SH mode in a Love wave state and the SH mode in a leaky state.

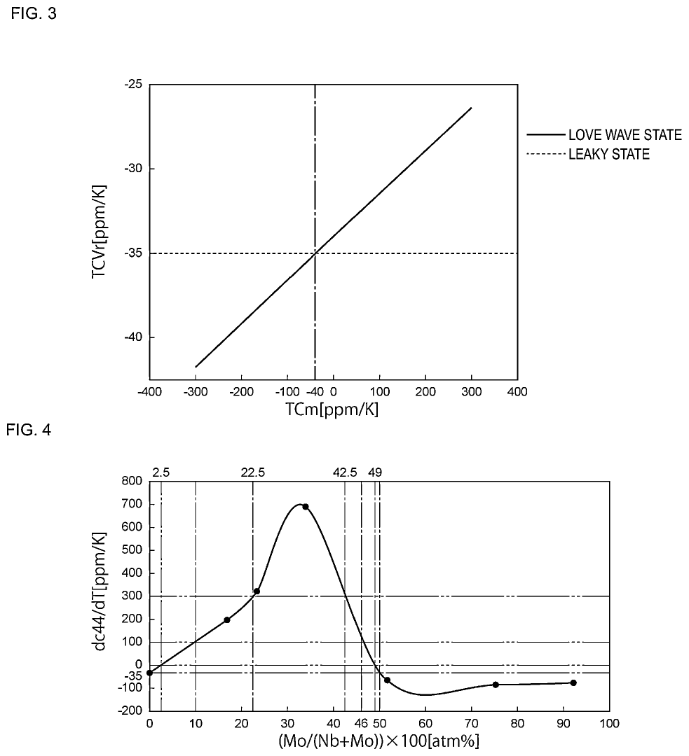

The SH mode is in a Love wave state when the normalized thickness of electrode fingers is at least about 10%, for example, as in this preferred embodiment. The relationship between the temperature coefficient TCm of the elastic modulus of electrode fingers and the acoustic velocity temperature coefficient TCVr at a resonance point, in the case where the normalized thickness of the electrode fingers is about 10%, was derived through a simulation. In the simulation, the IDT electrode was assumed to be made of hypothetical Mo, and the piezoelectric material layer was assumed to be made of 42YX—LiTaO₃. The temperature coefficient TCm of the elastic modulus was changed by changing the elastic moduluses c11 and c44 of the hypothetical Mo. The elastic moduluses c11 and c44 were set to the same value. The physical property values of the hypothetical Mo other than the elastic modulus value were the same as those of Mo. It is the elastic modulus c44 that contributes to the acoustic velocity temperature coefficient TCV. Accordingly, the temperature coefficient TCm of the elastic modulus herein indicates the temperature dependence of the elastic modulus c44. Thus, the temperature coefficient TCm of the elastic modulus corresponds to dc44/dT [ppm/K] which is the slope of time-dependent change in the elastic modulus c44. The results of the simulation are shown in FIG. 3. For comparison, the acoustic velocity temperature coefficient TCVr as observed when the SH mode is in a leaky state is also shown in FIG. 3.

FIG. 3 is a diagram showing the relationship between the temperature coefficient TCm of the elastic modulus of the electrode fingers and the acoustic velocity temperature coefficient TCVr at a resonance point when the normalized thickness of the electrode fingers is about 10%, for example. The broken line in FIG. 3 represents the acoustic velocity temperature coefficient TCVr at a resonance point when the SH mode is in a leaky state. The results obtained when the SH mode is in a leaky state correspond to the results obtained when the normalized thickness of the electrode fingers is less than about 10%, for example.

As shown in FIG. 3, when the SH mode is in a leaky state, the acoustic velocity temperature coefficient TCVr at the resonance point is about −35 ppm/K, for example. On the other hand, when the SH mode is in a Love wave state, the acoustic velocity temperature coefficient TCVr approaches 0 as the temperature coefficient TCm of the elastic modulus increases. FIG. 3 also indicates that when the temperature coefficient TCm of the elastic modulus is greater than or equal to about −40 ppm/K, for example, the acoustic velocity temperature coefficient TCVr in a Love wave state of the SH mode is greater than or equal to the acoustic velocity temperature coefficient TCVr in a leaky state of the SH mode.

However, the temperature coefficient TCm of the elastic modulus of an electrode material is generally lower than about −40 ppm/K. Table 1 shows the temperature coefficients TCm of the elastic modulus of typical materials used for IDT electrodes. As shown in Table 1, the temperature coefficients TCm of the elastic modulus of all the materials are lower than about −40 ppm/K. Therefore, in the conventional acoustic wave devices, the temperature characteristics are inferior in a Love wave state of the SH mode than in a leaky state of the SH mode. Table 2 shows example data for an acoustic wave device which uses Mo for an IDT electrode. As shown in Table 2, the absolute value of TCVr is larger in a Love wave state than in a leaky state.

TABLE 1

| Material | TCm [ppm/K] |
|---|---|
| Al | −590 |
| Cu | −270 |
| Mo | −130 |
| W | −99 |

TABLE 2

| Mo equivalent | TCVr | TCVa |
|---|---|---|
| thickness | [ppm/K] | [ppm/K] |
| 2% (leaky state) | −35 | −64 |
| 10% (Love wave state) | −42 | −62 |

On the other hand, Nb, Pd, NiFe, and an alloy including at least one of Nb and Pd have a relatively high temperature coefficient TCm of the elastic modulus. In this preferred embodiment, an alloy including Nb is used for the electrode layer(s) of the electrode fingers. Therefore, the temperature coefficient TCm of the elastic modulus of the electrode fingers can be increased, and the absolute value of the acoustic velocity temperature coefficient TCVr at a resonance point, or the like can be decreased. The temperature characteristics can thus be improved.

More specifically, in this preferred embodiment, NbMo as an alloy including Nb is used for the IDT electrode. FIG. 4 shows dc44/dT in NbMo. As described above, dc44/dT, which indicates the temperature dependence of the elastic modulus c44, corresponds to the temperature coefficient TCm of the elastic modulus. FIG. 4 is based on the description in a non-patent document (Hubbell, et al., Physics Letters A 39. 4 (1972): 261-262.).

FIG. 4 is a diagram showing the relationship between the content of Mo in NbMo and dc44/dT. The relationship shown in FIG. 4 is at about 25° C., for example. When the content of Mo is 0%, NbMo corresponds to Nb.

As can be seen in FIG. 4, the dc44/dT of Nb is about −35 ppm/K, for example. In the range where the Mo content in NbMo is up to about 33.6 atm %, for example, the dc44/dT of NbMo increases with increase in the Mo content. The dc44/dT reaches its peak at an Mo content of about 33.6 atm %, for example. The Mo content is preferably about 50 atm % or less, for example. In this case, the dc44/dT of NbMo can be made higher than the dc44/dT of Nb. The Mo content is more preferably not less than about 2.5 atm % and not more than about 49 atm %, for example. In this case, the dc44/dT can be made 0 ppm/K or more. The Mo content is even more preferably not less than about 10 atm % and not more than about 46 atm %, for example. In this case, the dc44/dT can be about 100 ppm/K or more, for example. The Mo content is still more preferably not less than about 22.5 atm % and not more than about 42.5 atm %, for example. In this case, the dc44/dT can be about 300 ppm/K or more, for example.

The use of such NbMo for the IDT electrode can increase the temperature coefficient TCm of the elastic modulus of the electrode fingers. This can decrease the absolute value of the acoustic velocity temperature coefficient TCVr at a resonance point, thus improving the temperature characteristics.

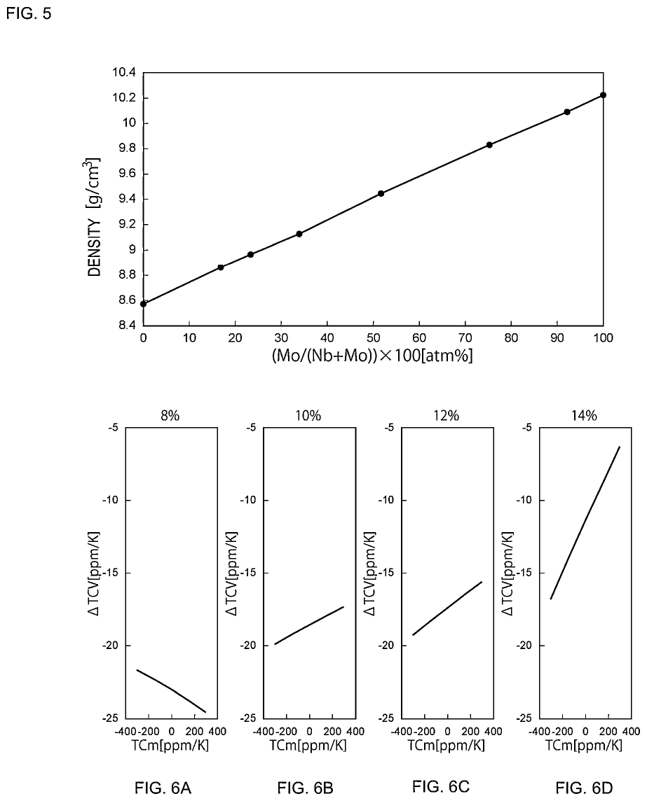

Further, a simulation was performed on electrode fingers made of Mo and electrode fingers made of NbMo with an Mo content of about 36%, for example, to compare them in terms of TCVr at a resonance point and TCVa at an anti-resonance point. In the simulation, the mass addition by the Mo electrode fingers was set to be equal to the mass addition by the NbMo electrode fingers. More specifically, the normalized thickness of the Mo electrode fingers was set to about 10%, while the normalized thickness of the NbMo electrode fingers was set to about 11%, for example. This is based on the relationship between the Mo content in NbMo and the density, shown in FIG. 5. The results of the simulation are shown in Table 3.

TABLE 3

| Material of | Normalized | TCVr | TCVa |
|---|---|---|---|
| electrode fingers | thickness | [ppm/K] | [ppm/K] |
| Mo | 10% | −42 | −62 |
| NbMo | 11% | −7 | −20 |

Table 3 indicates that compared to the use of Mo for the electrode fingers, the use of NbMo for the electrode fingers as in this preferred embodiment can decrease both the absolute value of the acoustic velocity temperature coefficient TCVr at a resonance point and the absolute value of the acoustic velocity temperature coefficient TCVa at an anti-resonance point. In this preferred embodiment, the SH mode is used in a Love wave state. Therefore, the higher the temperature coefficient TCm of the elastic modulus of the electrode fingers is, the lower can be made the absolute value of the acoustic velocity temperature coefficient TCV. Further, as shown in FIG. 4, when the Mo content in NbMo is, for example, about 36% dc44/dT, i.e., the temperature coefficient TCm of the elastic modulus, is as high as about 600 ppm/K, for example. Thus, the temperature characteristics can be further improved.

The relationship between the temperature coefficient TCm of the elastic modulus of electrode fingers and a difference ΔTCV in the acoustic velocity temperature coefficient, at varying thicknesses of the electrode fingers, was derived through a simulation. When the absolute value of the difference ΔTCV between the acoustic velocity temperature coefficient at a resonance point and that at an anti-resonance point is high, there is a difference in the width of the temperature-dependent change between the resonance point and the anti-resonance point. This may impair the stability of the electrical characteristics of the acoustic wave device. Thus, the lower the absolute value of the difference ΔTCV in the acoustic velocity temperature coefficient, the better the temperature characteristics.

FIG. 6A is a diagram showing the relationship between the temperature coefficient TCm of the elastic modulus of the electrode fingers and the difference ΔTCV in the acoustic velocity temperature coefficient when the normalized thickness of the electrode fingers is about 8%, for example. FIG. 6B is a diagram showing the relationship between the temperature coefficient TCm of the elastic modulus of the electrode fingers and the difference ΔTCV in the acoustic velocity temperature coefficient when the normalized thickness of the electrode fingers is about 10%, for example. FIG. 6C is a diagram showing the relationship between the temperature coefficient TCm of the elastic modulus of the electrode fingers and the difference ΔTCV in the acoustic velocity temperature coefficient when the normalized thickness of the electrode fingers is about 12%, for example. FIG. 6D is a diagram showing the relationship between the temperature coefficient TCm of the elastic modulus of the electrode fingers and the difference ΔTCV in the acoustic velocity temperature coefficient when the normalized thickness of the electrode fingers is about 14%, for example.

When the normalized thickness of the electrode fingers is about 8%, for example, the SH mode is in a leaky state. As shown in FIG. 6A, even in the case of such an SH mode, the difference ΔTCV [ppm/K] between the acoustic velocity temperature coefficient at a resonance point and that at an anti-resonance point has a dependence on the temperature coefficient TCm of the elastic modulus of the electrode fingers. However, when the SH mode is in a leaky state, the absolute value of the difference ΔTCV in the acoustic velocity temperature coefficient increases with increase in the temperature coefficient TCm of the elastic modulus.

As can be seen from comparison between FIGS. 6A and 6B, the relationship between the temperature coefficient TCm of the elastic modulus of the electrode fingers and the difference ΔTCV in the acoustic velocity temperature coefficient differs from each other. As shown in FIG. 6B, when the normalized thickness of the electrode fingers is about 10%, for example, the absolute value of the difference ΔTCV in the acoustic velocity temperature coefficient approaches 0 as the temperature coefficient TCm of the elastic modulus increases. The data thus confirms that when the normalized thickness of the electrode fingers is about 10% or more, for example, the SH mode is in a Love wave state. As shown in FIG. 6C or 6D, the absolute value of the difference ΔTCV in the acoustic velocity temperature coefficient is lower when the normalized thickness of the electrode fingers is about 12% or about 14%, for example. The normalized thickness of the electrode fingers is preferably about 12% or more, more preferably about 14% or more, for example. This can further improve the temperature characteristics. There is no particular limitation on the upper limit of the normalized thickness of the electrode fingers. However, the normalized thickness of the electrode fingers is preferably about 100% or less, for example. In this case, the electrode fingers can be formed well at high productivity.

The piezoelectric material used for the piezoelectric material layer 3 shown in FIG. 2 is preferably a rotated Y-cut crystal having a rotation angle of not less than about −30° and not more than about 70°, for example. This enables effective excitation of the SH mode.

In this preferred embodiment, the piezoelectric substrate preferably is composed solely of the piezoelectric material layer 3, for example. However, the piezoelectric substrate may be a laminated substrate including the piezoelectric material layer 3. The below-described second to fourth preferred embodiments each illustrate an example in which the piezoelectric substrate is a laminated substrate. Except for their respective piezoelectric substrates, the acoustic wave devices of the second to fourth preferred embodiments have the same construction as the acoustic wave device 1 of the first preferred embodiment. The acoustic wave devices of the second to fourth preferred embodiments can also improve the temperature characteristics.

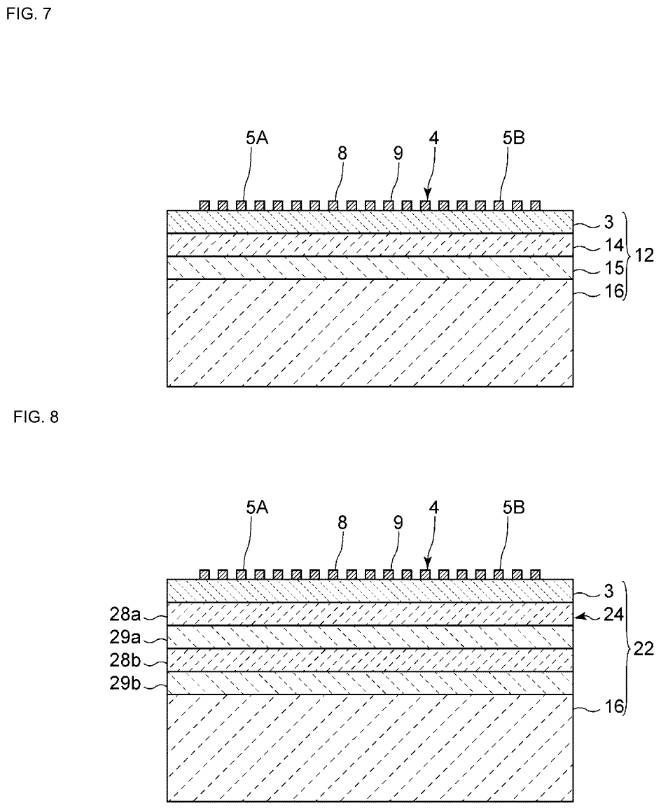

FIG. 7 is an elevational cross-sectional view of an acoustic wave device according to the second preferred embodiment.

The piezoelectric substrate 12 of this preferred embodiment includes a support substrate 16, a high acoustic velocity film 15 as a high acoustic velocity material layer, a low acoustic velocity film 14, and a piezoelectric material layer 3. The high acoustic velocity film 15 is provided on the support substrate 16. The low acoustic velocity film 14 is provided on the high acoustic velocity film 15. The piezoelectric material layer 3 is provided on the low acoustic velocity film 14.

The low acoustic velocity film 14 is a film of a relatively low acoustic velocity. More specifically, the acoustic velocity of bulk waves propagating in the low acoustic velocity film 14 is lower than the acoustic velocity of bulk waves propagating in the piezoelectric material layer 3. Examples of materials usable for the low acoustic velocity film 14 include glass, silicon oxide, silicon oxynitride, lithium oxide, tantalum pentoxide, and a material including, as a main component, a compound obtained by adding fluorine, carbon, or boron to silicon oxide.

The high acoustic velocity material layer is a layer of a relatively high acoustic velocity. In this preferred embodiment, the high acoustic velocity film 15 is the high acoustic material layer. The acoustic velocity of bulk waves propagating in the high acoustic velocity material layer is higher than the acoustic velocity of acoustic waves propagating in the piezoelectric material layer 3. The high acoustic velocity material layer may be made of a medium including, as a main component, silicon, aluminum oxide, silicon carbide, silicon nitride, silicon oxynitride, sapphire, lithium tantalate, lithium niobate, crystal, alumina, zirconia, cordierite, mullite, steatite, forsterite, DLC (diamond-like carbon) film, diamond, or the like.

Examples of materials usable for the support substrate 16 include piezoelectric materials such as aluminum oxide, lithium tantalate, lithium niobate, and crystal; ceramics such as alumina, sapphire, magnesia, silicon nitride, aluminum nitride, silicon carbide, zirconia, cordierite, mullite, steatite, and forsterite; dielectric materials such as diamond and glass; and semiconductors or resins such as silicon and gallium nitride.

In this preferred embodiment, the high acoustic velocity film 15 as a high acoustic velocity material layer, the low acoustic velocity film 14, and the piezoelectric material layer 3 are laminated in this order, so that the energy of acoustic waves can be effectively confined to the piezoelectric material layer 3.

The piezoelectric substrate may be a laminate of a support substrate, a high acoustic velocity film, and a piezoelectric material layer. Alternatively, the high acoustic velocity material layer may be a high acoustic velocity support substrate. In this case, the piezoelectric substrate may be, for example, a laminate of a high acoustic velocity support substrate, a low acoustic velocity film, and a piezoelectric material layer, or a laminate of a high acoustic velocity support substrate and a piezoelectric material layer. Also in such cases, the temperature characteristics can be improved as in the second preferred embodiment. Further, the energy of acoustic waves can be confined to the piezoelectric material layer.

FIG. 8 is an elevational cross-sectional view of an acoustic wave device according to the third preferred embodiment.

The piezoelectric substrate 22 of this preferred embodiment includes a support substrate 16, an acoustic reflection film 24, and a piezoelectric material layer 3. The acoustic reflection film 24 is provided on the support substrate 16. The piezoelectric material layer 3 is provided on the acoustic reflection film 24.

The acoustic reflection film 24 is a laminate of a plurality of acoustic impedance layers. More specifically, the acoustic reflection film 24 includes a plurality of low acoustic impedance layers and a plurality of high acoustic impedance layers. The low acoustic impedance layers are layers having a relatively low acoustic impedance. The low acoustic impedance layers of the acoustic reflection film 24 are a low acoustic impedance layer 28a and a low acoustic impedance layer 28b. On the other hand, the high acoustic impedance layers are layers having a relatively high acoustic impedance. The high acoustic impedance layers of the acoustic reflection film 24 are a high acoustic impedance layer 29a and a high acoustic impedance layer 29b. The low acoustic impedance layers and the high acoustic impedance layers are alternately arranged. The low acoustic impedance layer 28a is the layer located closest to the piezoelectric material layer 3 in the acoustic reflection film 24.

The acoustic reflection film 24 includes the two low acoustic impedance layers and the two high acoustic impedance layers. However, it is sufficient that the acoustic reflection film 24 includes at least one low acoustic impedance layer and at least one high acoustic impedance layer. Silicon oxide or aluminum, for example, can be used as a material for the low acoustic impedance layer(s). A metal such as platinum or tungsten, or a dielectric material such as aluminum nitride or silicon nitride, for example, can be used as a material for the high acoustic impedance layer(s).

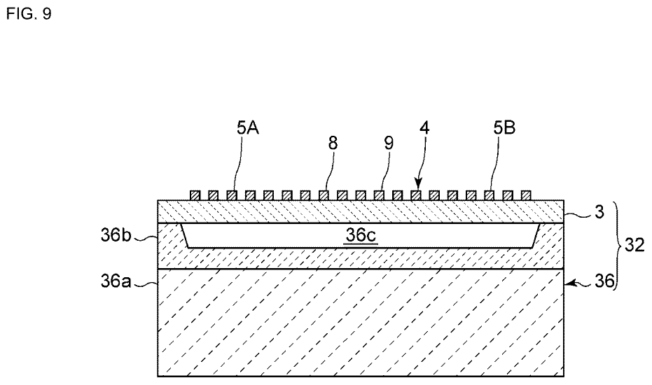

FIG. 9 is an elevational cross-sectional view of an acoustic wave device according to the fourth preferred embodiment.

The piezoelectric substrate 32 of this preferred embodiment includes a support 36 and a piezoelectric material layer 3. The support 36 includes a support substrate 36a and a dielectric layer 36b. The support substrate 36a has the same construction as the support substrate 16 of the second preferred embodiment and the support substrate 16 of the third preferred embodiment. The dielectric layer 36b is provided on the support substrate 36a. The piezoelectric material layer 3 is provided on the dielectric layer 36b. The support 36 has a cavity 36c. More specifically, the cavity 36c is a recess provided in the dielectric layer 36b. A hollow space is defined by covering the recess with the piezoelectric material layer 3. The cavity 36c overlaps at least a portion of the IDT electrode 4 in a planar view. The term “planar view” herein refers to a view from a downward direction, e.g., in FIG. 2 or 9.

The cavity 36c may be provided only in the support substrate 36a, or in an area extending over the support substrate 36a and the dielectric layer 36b. Alternatively, the cavity 36c may be a through-hole provided in at least one of the support substrate 36a and the dielectric layer 36b. The support 36 may be composed solely of the support substrate 36a, for example. In that case, the cavity 36c may be provided in the support substrate 36a.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric material layer; and
an IDT electrode on the piezoelectric material layer and including a plurality of electrode fingers arranged periodically; wherein
the electrode fingers each include at least one electrode layer including at least one of Nb, Pd, or Ni; and
a sum of thicknesses of the at least one electrode layer, calculated assuming that the at least one electrode layer includes Mo and based on a density ratio between the at least one electrode layer and Mo, is at least about 10% of a spatial period of the electrode fingers.

2. The acoustic wave device according to claim 1, wherein the piezoelectric material layer includes lithium tantalate.

3. The acoustic wave device according to claim 1, wherein the piezoelectric material layer includes lithium niobate.

4. The acoustic wave device according to claim 2, wherein the piezoelectric material layer includes a rotated Y-cut crystal with a rotation angle of not less than about −30° and not more than about 70°.

5. The acoustic wave device according to claim 1, wherein the at least one electrode layer includes NbMo, and a content of Mo in the NbMo is about 50 atm % or less.

6. The acoustic wave device according to claim 5, wherein the content of Mo in the NbMo is not less than about 2.5 atm % and not more than about 49 atm %.

7. The acoustic wave device according to claim 6, wherein the content of Mo in the NbMo is not less than about 10 atm % and not more than about 46 atm %.

8. The acoustic wave device according to claim 7, wherein the content of Mo in the NbMo is not less than about 22.5 atm % and not more than about 42.5 atm %.

9. The acoustic wave device according to claim 1, wherein the piezoelectric material layer is included in a laminated substrate defining a piezoelectric substrate.

10. The acoustic wave device according to claim 1, wherein the piezoelectric material layer alone defines a piezoelectric substrate.

11. The acoustic wave device according to claim 1, wherein the acoustic wave device is structured to generate an SH mode.

12. The acoustic wave device according to claim 11, wherein the SH mode is in a Love wave state.

13. The acoustic wave device according to claim 1, further comprising reflectors on both sides of the IDT electrode.

14. The acoustic wave device according to claim 1, wherein the acoustic wave device is a surface acoustic wave resonator.

15. The acoustic wave device according to claim 1, wherein the acoustic wave device is a filter device or a multiplexer.

16. The acoustic wave device according to claim 1, wherein the piezoelectric material layer includes 42YX—LiTaO₃.

17. The acoustic wave device according to claim 1, wherein the IDT electrode includes multiple electrode layers.

18. The acoustic wave device according to claim 13, wherein a material of the reflectors is same as a material of the IDT electrode.

19. The acoustic wave device according to claim 1, wherein a normalized thickness of the electrode fingers is about 10%.

20. The acoustic wave device according to claim 1, wherein a normalized thickness of the electrode fingers is about 12% or about 14%.
